(19) United States
(12) Patent Application Publication
(10) Pub. No.: US 2026/0221188 A1
(43) Pub. Date: Jul. 30, 2026

(54) OPERATION METHOD OF MEMORY, MEMORY, MEMORY SYSTEM AND ELECTRONIC APPARATUS

(71) Applicant: YANGTZE MEMORY TECHNOLOGIES CO., LTD., Wuhan (CN)

(72) Inventors: Yu ZHANG, Wuhan (CN); Lei JIN, Wuhan (CN); Da LI, Wuhan (CN); Wei QI, Wuhan (CN); Ya WANG, Wuhan (CN); ZongLiang HUO, Wuhan (CN)

(21) Appl. No.: 19/236,752

(22) Filed: Jun. 12, 2025

(30) Foreign Application Priority Data
Jan. 24, 2025 (CN) 2025101208096

(51) Int. Cl. G11C 16/08; G11C 16/26

(52) U.S. Cl. CPC G11C 16/08; G11C 16/26

(57) ABSTRACT

A method includes discharging a voltage of a first word line to a first voltage after performing a first read operation on a first memory cell; floating the first word line after discharging the voltage of the first word line to the first voltage; applying a second voltage to the first word line in a first phase of performing a second read operation on the first memory cell, wherein the second read operation is after floating the first word line, and the second voltage is greater than the first voltage; and applying a pre pulse voltage to the first word line in a second phase of performing the second read operation, wherein the second phase is after the first phase, and the pre pulse voltage is greater than the second voltage.

### CROSS-REFERENCE TO RELATED APPLICATIONS

The present disclosure claims priority to Chinese Patent Application No. 2025101208096, which was filed January 24, 2025, and is hereby incorporated herein by reference in its entirety.

### TECHNICAL FIELD

Examples of the present disclosure relate to the field of memory technology, and in particular, to an operation method of a memory, a memory, a memory system, and an electronic apparatus.

### BACKGROUND

In a process of reading a memory cell in a memory, before applying a read voltage to a word line coupled to the memory cell, a pre pulse voltage may be applied to the word line to smooth a channel potential of the memory cell, thereby mitigating generation of hot electron injection (HCI).

### SUMMARY

The examples of the present disclosure provide an operation method of a memory, a memory, a memory system and an electronic apparatus. The technical solutions provided in the examples of the present disclosure are as follows.

According to an aspect of the examples of the present disclosure, an operation method of a memory is provided, in which the memory includes a memory cell array, the memory cell array including a first memory cell coupled with a first word line, the method includes: discharging a voltage of the first word line to a first voltage after performing a first read operation on the first memory cell; floating the first word line after discharging the voltage of the first word line to the first voltage; applying a second voltage to the first word line in a first phase of performing a second read operation on the first memory cell, wherein the second read operation is after floating the first word line and the second voltage is greater than the first voltage; and applying a pre pulse voltage to the first word line in a second phase of performing the second read operation, wherein the second phase is after the first phase and the pre pulse voltage is greater than the second voltage.

According to an aspect of the examples of the present disclosure, a memory is provided, in which the memory includes a peripheral circuit and a memory cell array, the memory cell array including a first memory cell coupled with a first word line, and the peripheral circuit being configured to: discharging a voltage of the first word line to a first voltage after performing a first read operation on the first memory cell; floating the first word line after discharging the voltage of the first word line to the first voltage; applying a second voltage to the first word line in a first phase of performing a second read operation on the first memory cell, wherein the second read operation is after floating the first word line and the second voltage is greater than the first voltage; and applying a pre pulse voltage to the first word line in a second phase of performing the second read operation, wherein the second phase is after the first phase and the pre pulse voltage is greater than the second voltage.

According to an aspect of the examples of the present disclosure, a memory system is provided, in which the memory system includes: at least one memory including a peripheral circuit and a memory cell array, the memory cell array including a plurality of memory cells, and the peripheral circuit being configured to carry out the foregoing operation method of the memory; and a controller coupled to the at least one memory to control the at least one memory to store data.

According to an aspect of the examples of the present disclosure, an electronic apparatus is provided, in which the electronic apparatus includes a host and a memory system coupled to the host, wherein the memory system includes: at least one memory including a peripheral circuit and a memory cell array, the memory cell array including a plurality of memory cells, and the peripheral circuit being configured to carry out the foregoing operation method of the memory; and a controller coupled to the at least one memory to control the at least one memory to store data.

The technical solutions provided in the examples of the present disclosure at least include the following beneficial effects.

In the second read operation, the second voltage is firstly applied to the first word line coupled with the first memory cell, then the voltage of the first word line is pulled up to the pre pulse voltage by taking the second voltage as a starting voltage. Since the second voltage is greater than the voltage (the first voltage) to which the first word line is discharged after the last read operation (for the first memory cell), the above method can utilize the voltage generated by floating the first word line in an interval time period between the first read operation and the second read operation, to apply the pre pulse voltage to the first word line, which has a smaller boosting magnitude, thereby achieving reasonable control of the boosting process.

### BRIEF DESCRIPTION OF THE DRAWINGS

FIG. 1 is a block diagram of an electronic apparatus with a memory system provided by an example of the present disclosure;

FIG. 2 is a schematic diagram of a memory card provided by an example of the present disclosure;

FIG. 3 is a schematic diagram of a solid-state drive provided by an example of the present disclosure;

FIG. 4 is a schematic diagram of a memory provided by an example of the present disclosure;

FIG. 5 is a flowchart of an operation method of a memory provided by an example of the present disclosure;

FIG. 6 is a schematic diagram of a voltage variation of a first word line provided by an example of the present disclosure;

FIG. 7 is a schematic diagram of a voltage variation of a first word line provided by another example of the present disclosure;

FIG. 8 is a schematic diagram of a sequential read process provided by an example of the present disclosure;

FIG. 9 is a flowchart of an operation method of a memory provided by another example of the present disclosure;

FIG. 10 is a flowchart of an operation method of a memory provided by another example of the present disclosure;

FIG. 11 is a schematic diagram of a voltage variation of a second word line provided by an example of the present disclosure;

FIG. 12 is a schematic diagram of a voltage variation of a second word line provided by another example of the present disclosure;

FIG. 13 is a schematic diagram of a voltage variation of a first TSG / first BSG provided by an example of the present disclosure;

FIG. 14 is a schematic diagram of a voltage variation of a second TSG provided by an example of the present disclosure;

FIG. 15 is a schematic diagram of a voltage variation related to a read operation provided by an example of the present disclosure;

FIG. 16 is a schematic diagram of a voltage variation related to a read operation provided by another example of the present disclosure;

FIG. 17 is a schematic diagram of a memory provided by another example of the present disclosure;

FIG. 18 is a schematic diagram of a sending process of read instructions provided by an example of the present disclosure;

FIG. 19 is a schematic diagram of a sending process of read instructions provided by another example of the present disclosure;

FIG. 20 is a block diagram of an electronic apparatus provided by an example of the present disclosure.

### DETAILED DESCRIPTION

To make the objectives, technical solutions, and advantages of the present disclosure clearer, the examples of the present disclosure will be further described in detail below with reference to the accompanying drawings.

It should be noted that the terms “first”, “second”, and the like in the present disclosure are used to distinguish similar objects, and are not necessarily used to describe a specific order or sequence. It should be understood that the terms used in this way may be interchanged under appropriate circumstances, so that the examples of the present disclosure can be implemented in various orders. The implementations described in the following example implementations do not represent all implementations consistent with the present disclosure. Rather, they are merely examples consistent with some aspects of the present disclosure.

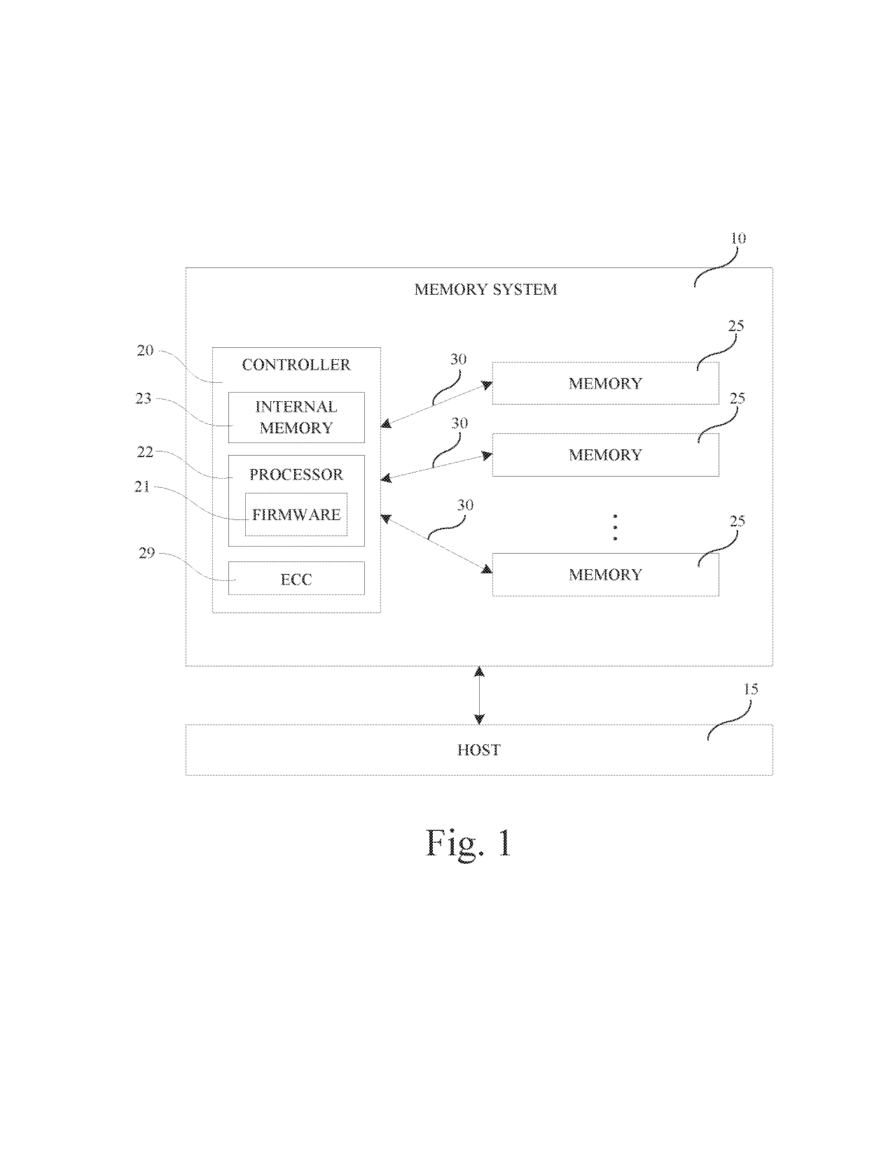

Please refer to FIG. 1, which shows a block diagram of an electronic apparatus with a memory system provided by an example of the present disclosure. In some examples, the electronic apparatus may be a mobile phone, a desktop computer, a laptop computer, a tablet computer, a vehicle-mounted computer, a game console, a printer, a positioning apparatus, a wearable electronic apparatus, an intelligent sensor, a virtual reality (VR) apparatus, an augmented reality (AR) apparatus, or any other suitable electronic apparatus having a memory system therein. The memory system 10 may include a controller 20 and one or more semiconductor memories 25. Each of the semiconductor memories 25 (hereinafter referred to as “memory” for short) may be a Flash memory (e.g., NAND (Not NAD) flash memory, NOR (Not OR) flash memory, etc.). The memory system 10 may communicate with the host 15 through the controller 20, which may be connected to the one or more memories 25 via one or more channels 30. In some examples, each of the memories 25 may be managed by the controller 20 via the one or more channels 30.

In some examples, the host 15 may include a processor of the electronic apparatus, such as a central processing unit (CPU), or a system on chip (SoC), such as an disclosure processor (AP). The host 15 may send data to be stored in the memory system 10 and/or may retrieve data from the memory system 10.

In some examples, the controller 20 may process I/O (Input/Output) requests received from the host 15, ensure data integrity and efficient storage, and manage the memory 25. To perform these tasks, the controller 20 may run a firmware 21, which may be executed by one or more processors 22 (e.g., microcontroller units, CPU) of the controller 20. For example, the controller 20 may run the firmware 21 to map a logical address (e.g., an address used by the host associated with host data) to a physical address (e.g., an actual location where the data is stored) in the memory 25. The controller 20 also runs the firmware 21 to manage defective memory blocks in the memory 25, in which the firmware 21 may remap the logical address to a different physical address, e.g., move the data to a different physical address. The controller 20 further includes an internal memory 23 (for example, a read-only memory (ROM), a random-access memory (RAM), a cache, etc.), and the internal memory 23 may be configured to store various metadata used by the firmware 21. In some examples, the controller 20 may also perform error recovery through an error correction code (ECC) engine 29. The ECC engine 29 is configured to detect and correct raw bit errors occurring within each of the memories 25.

In some examples, the channel 30 may provide data and control communications between the controller 20 and each of the memories 25 over a data bus. The controller 20 may select a certain memory 25 according to a chip enable signal.

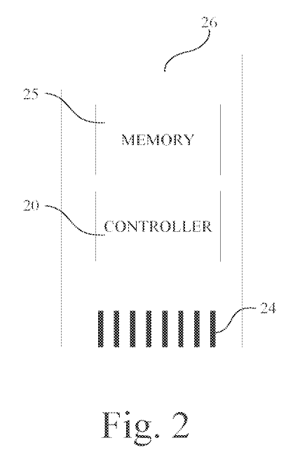

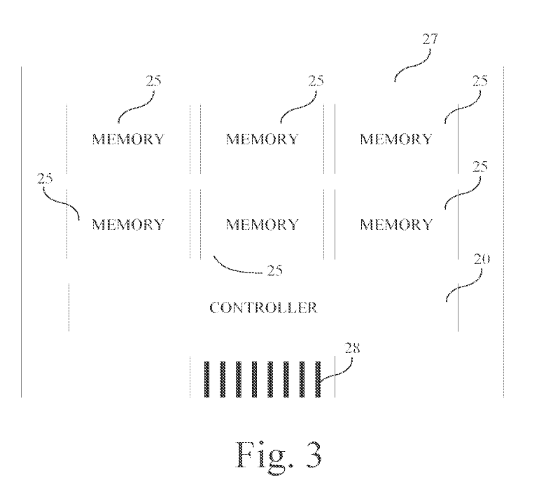

In some examples, the controller 20 and the one or more memories 25 may be integrated into various types of memory systems, for example, included in the same package, such as a Universal Flash Storage (UFS) package or an embedded Multi-Media Card (eMMC) package. For example, the memory system 10 may be implemented and packaged into different types of terminal electronic products. In an example as shown in FIG. 2, the controller 20 and the single memory 25 may be integrated into the memory card 26. The memory card 26 may include a PC (Personal Computer Memory Cards International Association, PCMCIA) card, a Compact Flash (CF) card, a Smart Media (SM) card, a memory stick, a multimedia card (MMC, RS-MMC, MMCmicro), an SD card (SD, miniSD, microSD, SDHC), a UFS, or the like. The memory card 26 may also include a memory card connector 24 that couples the memory card 26 with a host (e.g., the host 15 in FIG. 1). In another example shown in FIG. 3, the controller 20 and the plurality of memories 25 may be integrated into a solid-state drive (SSD) 27. SSD 27 may also include an SSD connector 28 that couples the SSD 27 with a host (e.g., the host 15 in FIG. 1).

The controller 20 may communicate with an external apparatus (e.g., the host 15) according to a communication protocol. For example, the controller 20 may communicate with the external apparatus through at least one of various interface protocols, such as a Universal Serial Bus (USB) protocol, an MMC protocol, a Peripheral Component Interconnect (PCI) protocol, a PCI-Express (PCI-E) protocol, an Advanced Technology Attachment (ATA) protocol, a Serial ATA (SATA) protocol, a parallel ATA protocol, a Small Computer System Interface (SCSI) protocol, an Enhanced Small Drive Interface (ESDI) protocol, an Integrated Drive Electronics (IDE) protocol, a Firewire protocol, an Non-Volatile Memory Express (NVMe) protocol, and the like.

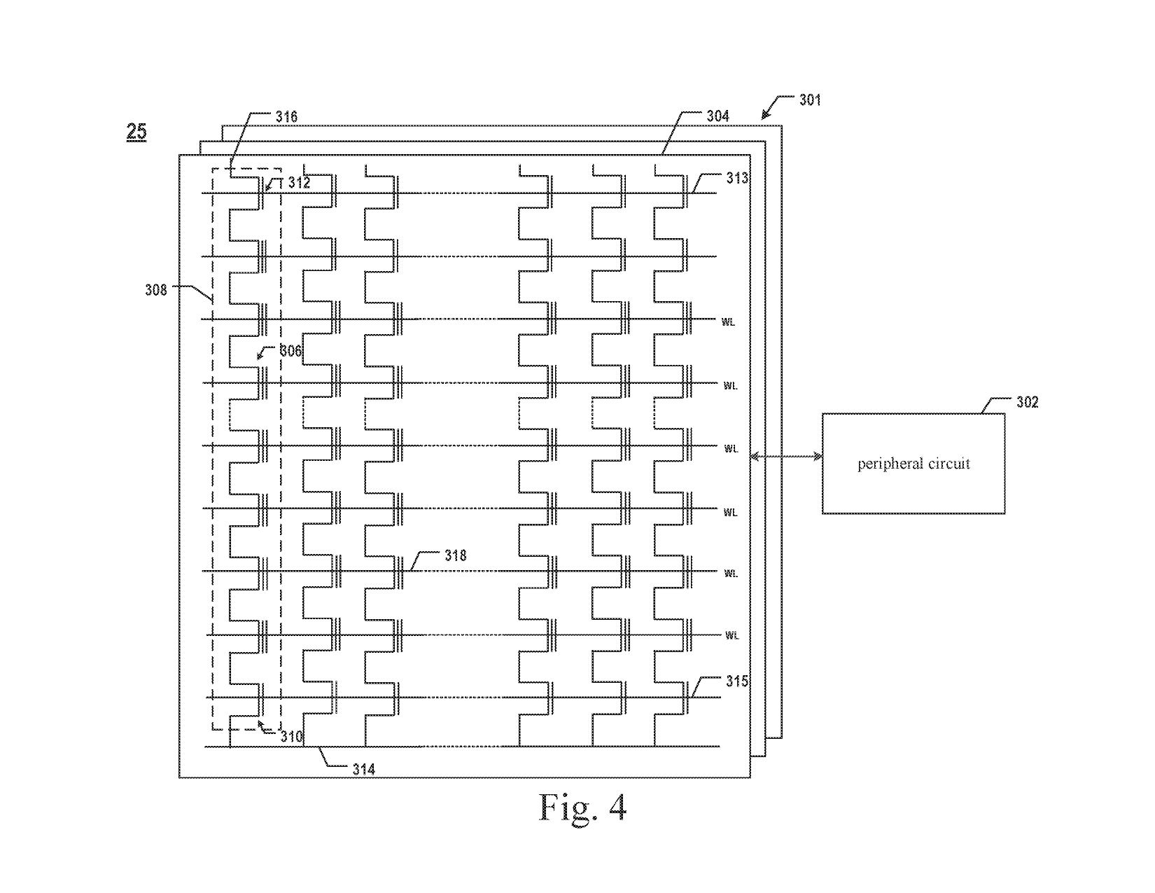

Please refer to FIG. 4, which illustrates a schematic diagram of a memory provided by an example of the present disclosure. As shown in FIG. 4, the memory 25 includes a memory cell array 301 and a peripheral circuit 302. The memory cell array 301 includes a plurality of memory strings 308 arranged in an array above a substrate (not shown in FIG. 4), with each of the memory strings 308 extending vertically above the substrate. Each of the memory strings 308 includes a plurality of memory cells 306 vertically stacked above the substrate. Each of the memory cells 306 has a function of storing data, the stored data is determined by an amount of electrons stored in the memory cell 306, and the amount of electrons stored in the memory cell 306 can determine the threshold voltage of the memory cell 306, therefore, the threshold voltage of the memory cell 306 can indicate the data stored therein. The memory cell 306 is a floating gate field effect transistor or a charge trap type field effect transistor. Each of the memory strings 308 further includes an upper select transistor 312 and a lower select transistor 310, and the upper select transistors 312 at the same height or similar heights from a carrying surface of the substrate in different memory strings 308 are coupled to a same drain select line (DSL) 313. The lower select transistors 310 at the same height or similar heights from the carrying surface of the substrate in different memory strings 308 are coupled to a same source select line (SSL) 315. The upper select transistor 312 and the lower select transistor 310 are configured to activate a selected memory string when erasing, programming, or reading the memory cell. The upper select transistor 312 is also referred to as a top select gate (TSG), and the lower select transistor 310 is also referred to as a bottom select gate (BSG). One end of the memory string 308 (the upper select transistor 312) is coupled to a bit line 316, the other end of the memory string 308 (the lower select transistor 310) is coupled to the source line (SL) 314, and each memory cell in the memory cell array is coupled to a respective word line 318. The memory strings 308 in the memory cell array 301 may be organized into a plurality of memory blocks 304, and source ends of respective memory strings 308 in the same memory block 304 are coupled to the same source line 314, for example, the respective memory strings 308 in the same memory block 304 have a common source line 314. The peripheral circuit 302 may include any analog, digital, and mixed signal circuit. For example, the peripheral circuit 302 includes page buffers/sense amplifiers, column decoders/bit line drivers, row decoders/word line drivers, voltage generators, control logic, registers, interfaces, and data buses, among others.

In the memory cell array, if a selected memory cell is to be read, a select voltage needs to be applied to the TSG and BSG in the selected memory string where the selected memory cell is located to activate the selected memory string, and unselected memory cells other than the selected memory cell in the selected memory string are turned on. Then, a read voltage is applied to the selected word line coupled to the selected memory cell, and the state of the threshold voltage of the selected memory cell may be determined by detecting the voltage variation of the bit line coupled to the selected memory string, thereby the selected memory cell is read. In the above process, before the read voltage is applied to the selected word line, since the turn-on voltage (and the select voltage) applied to the unselected word line coupled to the unselected memory cell is large, a similarly large pre pulse voltage needs to be applied to the selected word line, to smooth the electric potential. In addition, in the read operation of the memory, in order to pull up the voltage of the word line, the word line is required to have a determined initial level. Thus, in some examples, at the beginning of the read operation, the voltage of the selected word line is often discharged directly to Vdd (the drain voltage) and then boosted from Vdd. However, an amplitude difference between Vdd and the pre pulse voltage is relatively large, and in some scenarios, the foregoing solution can still be optimized.

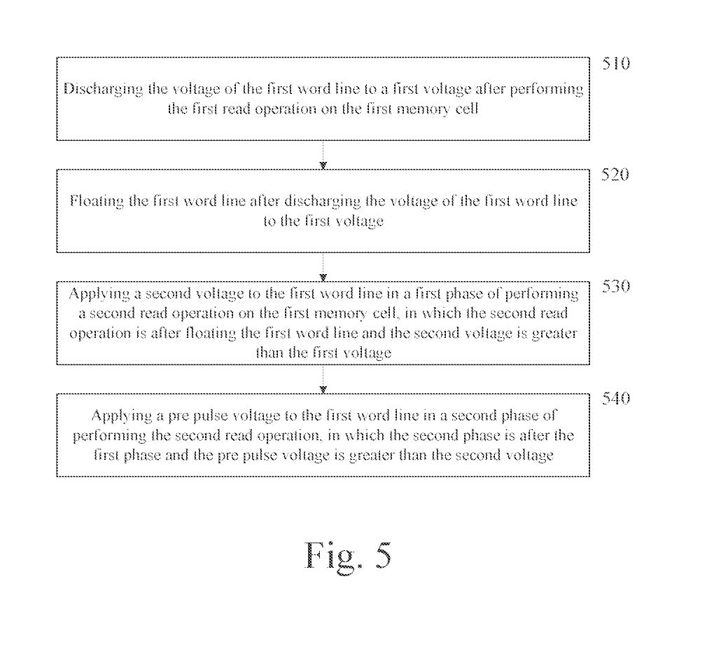

Please refer to FIG. 5, which shows a flowchart of an operation method of a memory provided by an example of the present disclosure. The memory includes a memory cell array including a first memory cell coupled with a first word line. The method includes at least one of the following operations 510 to 540.

Operation 510: discharging a voltage of the first word line to a first voltage after performing a first read operation on the first memory cell.

In some examples, the first voltage is Vdd. For example, after performing the first read operation on the first memory cell, the voltage of the first word line is discharged to Vdd.

In some examples, the first memory cell is Multi-Level Cell (MLC), Trinary-Level Cell (TLC) or Quad-Level Cell (QLC). In some examples, the data stored in the first memory cell belongs to at least two pages. The first read operation is configured to read data of one of the at least two pages from the first memory cell.

Operation 520: floating the first word line after discharging the voltage of the first word line to the first voltage.

It should be understood that when an element (or component, assembly, member, etc.) is referred to as floating, it is intended to illustrate that the element does not form an electrical path with other elements. During floating the first word line, no voltage is applied to the first word line.

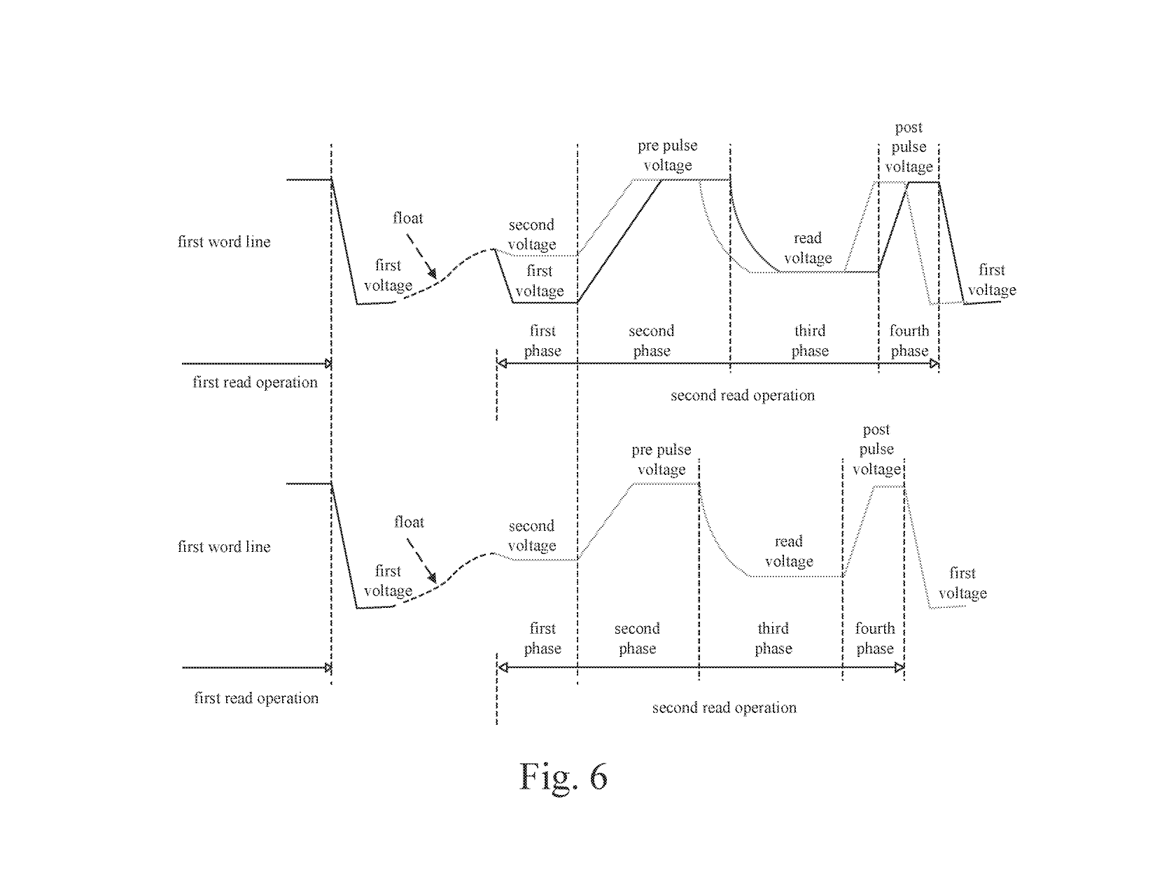

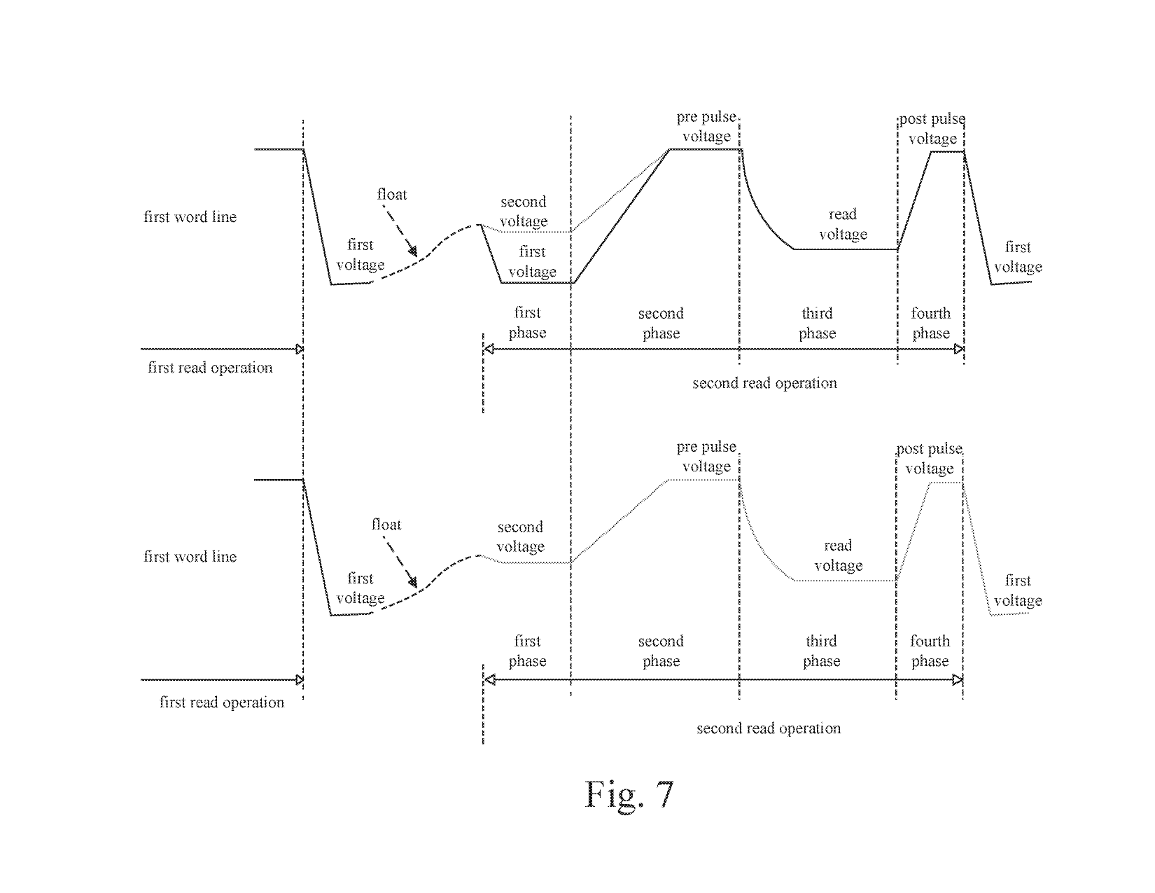

In some examples, during floating the first word line, the first word line generates a floating voltage that is greater than the first voltage. For example, as depicted by the voltage variation of the first word line shown in FIG. 6 (or FIG. 7), during floating the first word line, the first word line generates the floating voltage, and as the floating voltage is a voltage naturally generated by the first word line, the floating voltage is not a stable level.

Operation 530: applying a second voltage to the first word line in a first phase of performing a second read operation on the first memory cell, in which the second read operation is after floating the first word line and the second voltage is greater than the first voltage.

In some examples, the data read from the first memory cell by the first read operation and the data read from the first memory cell by the second read operation belong to different pages. For example, the first memory cell is an MLC and stores 2 bits of data, and 1 bit of data read from the first memory cell by the first read operation and 1 bit of data read from the first memory cell by the second read operation belong to different pages.

In some examples, a start time point of the first phase of the second read operation is a start time point of the second read operation.

For example, please refer to the voltage variation of the first word line indicated by the light-colored line in FIG. 6 (or FIG. 7), since the first word line generates the floating voltage during floating the first word line, then in the first stage of performing the second read operation, applying the second voltage to the first word line does not need to pull up the voltage of the first word line, thereby effectively utilizing the floating voltage.

Operation 540: applying a pre pulse voltage to the first word line in a second phase of performing the second read operation, in which the second phase is after the first phase and the pre pulse voltage is greater than the second voltage.

For example, please refer to the voltage variation of the first word line indicated by the light-colored line in FIG. 6 (or FIG. 7), since the second voltage applied to the first word line is greater than the first voltage in the first phase, when the pre pulse voltage is applied to the first word line in the second phase, the voltage of the first word line can be pulled up to the pre pulse voltage with a smaller boosting magnitude.

According to the technical solution provided by the example of the present disclosure, in the second read operation, the second voltage is firstly applied to the first word line coupled with the first memory cell, then the voltage of the first word line is pulled up to the pre pulse voltage by taking the second voltage as the initial voltage, and since the second voltage is greater than the voltage (the first voltage) to which the first word line is discharged after the last read operation (for the first memory cell), the above mentioned method can utilize the voltage generated by floating the first word line in an interval time period between the first read operation and the second read operation to apply the pre pulse voltage to the first word line, which has a relatively small boosting magnitude, thereby achieving reasonable control of the boosting process.

In some examples, the above method further includes at least one of the following operations 550 to 570 (not shown in FIG. 5).

Operation 550: applying a read voltage to the first word line in a third phase of performing the second read operation, in which the third phase is after the second phase and the read voltage is less than the pre pulse voltage.

For example, please refer to the voltage variation of the first word line indicated by the light-colored line (or the dark-colored line) in FIG. 6 (or FIG. 7), since a larger pre pulse voltage is applied to the first word line before the read voltage is applied to the first word line, in the third phase, the first word line will undergo a buck process. In addition, it should be noted that the read voltage applied to the first word line in the figures is an illustration. Those skilled in the art should understand that, in the third phase, the read voltage applied to the first word line may also vary, for example, in the third phase, a plurality of different read voltages may be sequentially applied to the first word line, which is not limited in the present disclosure.

Operation 560: applying a post pulse voltage to the first word line in a fourth phase of performing the second read operation, in which the post pulse voltage is greater than the read voltage and the fourth phase is after the third phase.

In some examples, the amplitude of the post pulse voltage is equal to the amplitude of the pre pulse voltage.

For example, please refer to the voltage variation of the first word line indicated by the light-colored line (or the dark-colored line) in FIG. 6 (or FIG. 7), since the read voltage less than the post pulse voltage is applied to the first word line before the post pulse voltage is applied to the first word line, in the fourth stage, the first word line will undergo a boosting process.

Operation 570: discharging the voltage of the first word line to the first voltage after performing the second read operation.

In some examples, an end time point of the fourth stage of performing the second read operation is an end time point of the second read operation.

For example, please refer to the voltage variation of the first word line indicated by the light-colored line (or the dark-colored line) in FIG. 6 (or FIG. 7), after the second read operation is performed (similar to after the first read operation is performed), the voltage of the first word line also needs to be discharged to the first voltage.

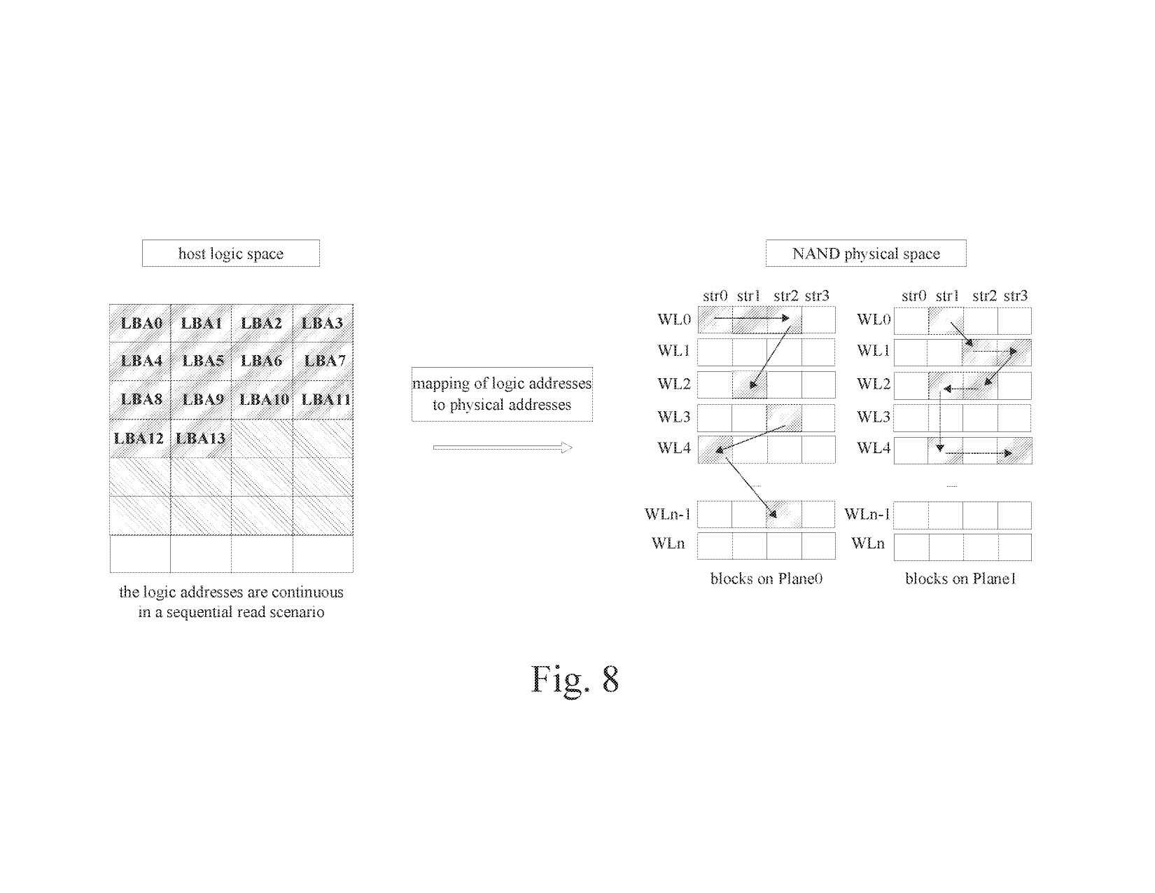

In the above example, by using the floating voltage of the first word line in the interval for the two read operations, the first word line starts boosting from a larger second voltage in a subsequent read operation. However, after the first word line is floated for a long time, the floating voltage would drop to a lower amplitude. Therefore, the foregoing solution is applicable to a scenario where the two read operations for the first memory cell are relatively close in time. For example, the foregoing solution is applicable to sequential read scenarios. Sequential read refers to read operations performed sequentially by consecutive logical addresses. For example, please refer to FIG. 8, which illustrates a schematic diagram of a sequential read process provided by an example of the present disclosure. It can be seen that, in a sequential read scenario, consecutive logical addresses are mapped to a same memory block in the memory, for example, a same memory block on plane0 and a same memory block on plane 1 in the memory. Further, the consecutive logical addresses may be mapped to a same memory cell in the same memory block (logical addresses of multiple bits stored in that memory cell are consecutive), therefore, in the sequential read scenario, the time of the two read operations for the same memory cell would be relatively close, while in a random read scenario, this condition cannot be guaranteed. In the following examples, how to reasonably apply this solution in the memory to consider different scenarios would be described.

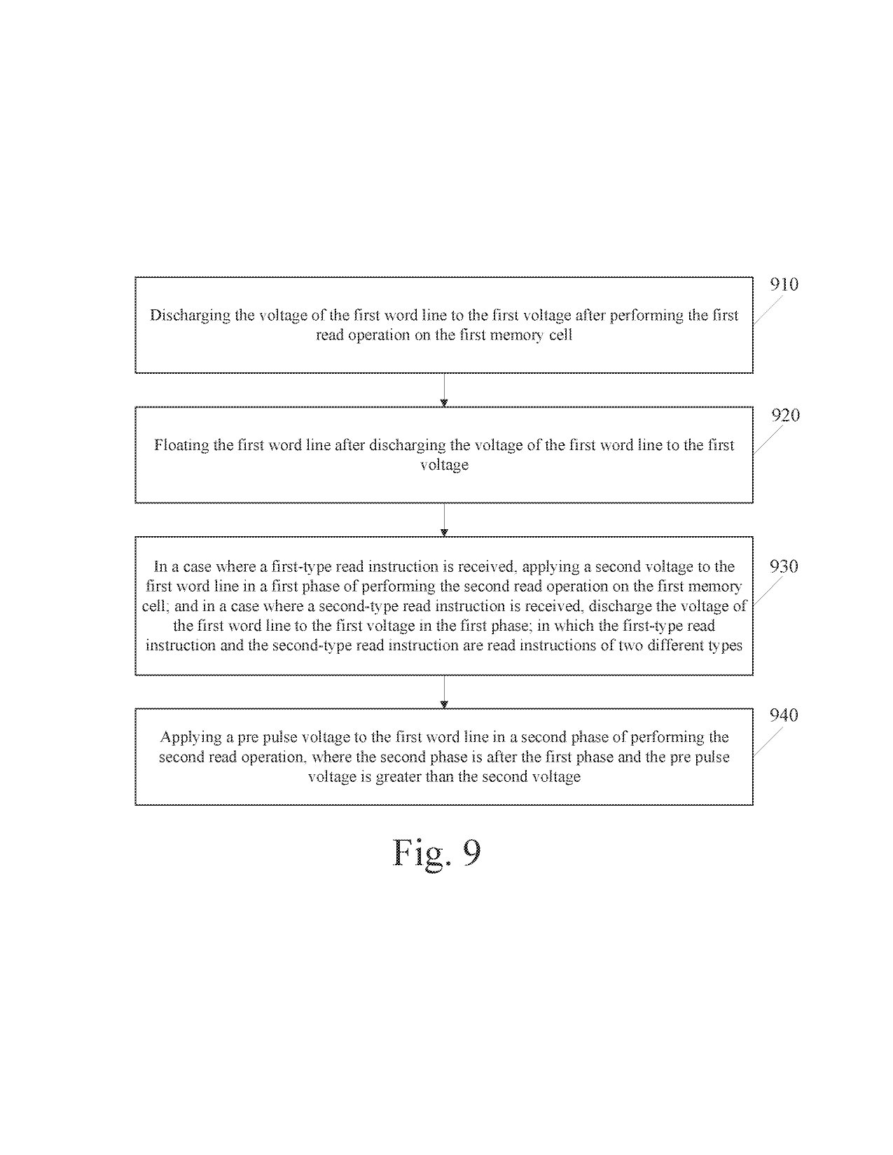

Please refer to FIG. 9, which illustrates a flowchart of an operation method of a memory provided by another example of the present disclosure. The memory includes a memory cell array including a first memory cell coupled with a first word line. The method includes at least one of the following operations 910 to 940.

Operation 910: discharging a voltage of the first word line to a first voltage after performing a first read operation on the first memory cell.

Operation 920: floating the first word line after discharging the voltage of the first word line to the first voltage.

Operation 930: in a case where a first-type read instruction is received, applying a second voltage to the first word line in a first phase of performing a second read operation on the first memory cell; and in a case where a second-type read instruction is received, discharge the voltage of the first word line to the first voltage in the first phase; in which the first-type read instruction and the second-type read instruction are read instructions of two different types.

For example, in a case where the first-type read instruction is received, please refer to the voltage variation of the first word line indicated by the light-colored line in FIG. 6 (or FIG. 7), the second voltage is applied to the first word line in the first stage of performing the second read operation. In a case where the second-type read instruction is received, please refer to the voltage variation of the first word line indicated by the dark-colored line in FIG. 6 (or FIG. 7), the voltage of the first word line is discharged to the first voltage in the first phase.

Operation 940: applying a pre pulse voltage to the first word line in a second phase of performing the second read operation, in which the second phase is after the first phase and the pre pulse voltage is greater than the second voltage.

For example, in a case where the first-type read instruction is received, please refer to the voltage variation of the first word line indicated by the light-colored line in FIG. 6 (or FIG. 7), the voltage of the first word line is pulled up to the pre pulse voltage from the second voltage in the second phase of performing the second read operation. In a case where the second-type read instruction is received, please refer to the voltage variation of the first word line indicated by the dark-colored line in FIG. 6 (or FIG. 7), the voltage of the first word line is pulled up to the pre pulse voltage from the first voltage in the second phase.

According to the technical solution provided by the example of the present disclosure, the read operation is controlled by designing two types of different reading instructions, so that the memory supports the use of two different ways to apply word line voltages in the read operation, thereby considering different read scenarios.

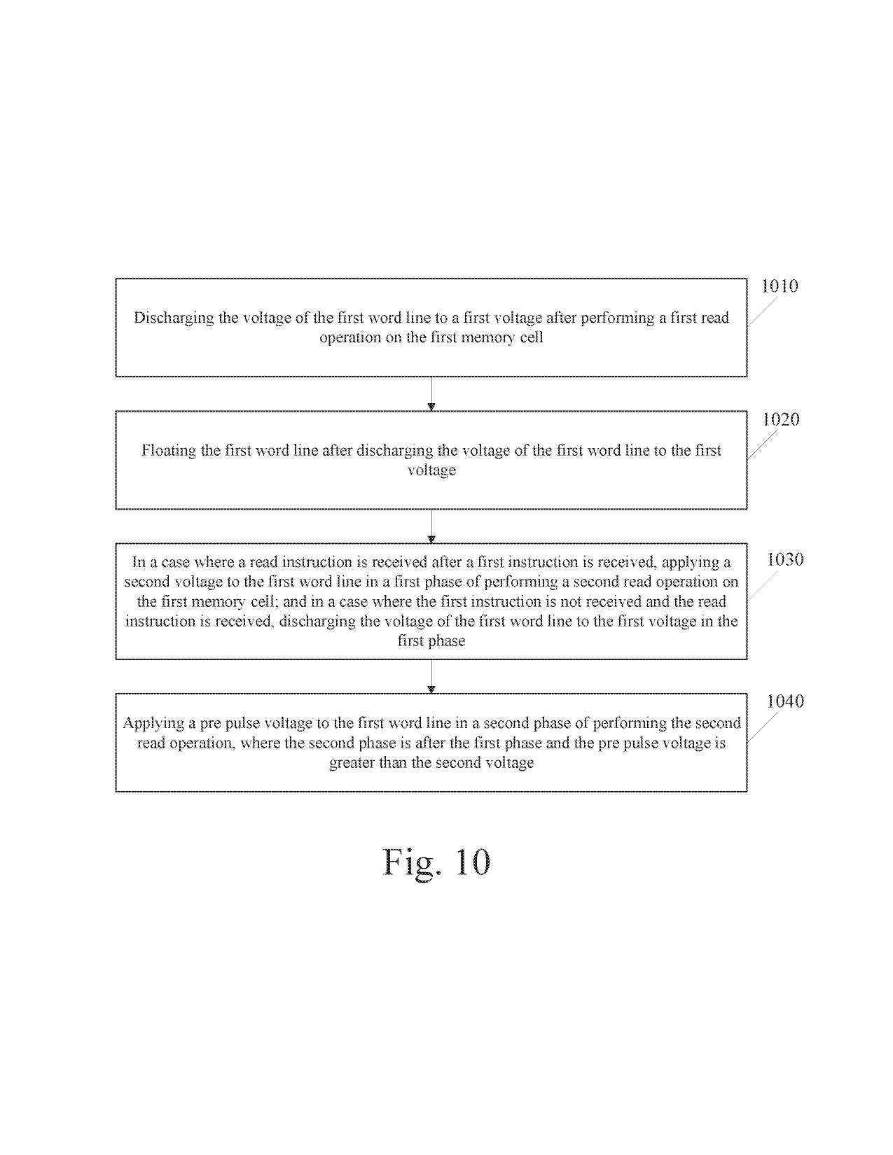

Please refer to FIG. 10, which illustrates a flowchart of an operation method of a memory provided by another example of the present disclosure. The memory includes a memory cell array including a first memory cell coupled with a first word line. The method includes at least one of the following operations 1010 to 1040.

Operation 1010: discharging a voltage of the first word line to a first voltage after performing a first read operation on the first memory cell.

Operation 1020: floating the first word line after discharging the voltage of the first word line to the first voltage.

Operation 1030: in a case where a read instruction is received after a first instruction is received, applying a second voltage to the first word line in a first phase of performing a second read operation on the first memory cell; and in a case where the first instruction is not received and the read instruction is received, discharging the voltage of the first word line to the first voltage in the first phase.

In some examples, the first instruction is a Set Feature instruction.

For example, in the case where the read instruction is received after the first instruction is received, please refer to the voltage variation of the first word line indicated by the light-colored line in FIG. 6 (or FIG. 7), the second voltage is applied to the first word line in the first stage of performing the second read operation. In the case where the first instruction is not received and the read instruction is received, please refer to the voltage variation of the first word line indicated by the dark-colored line in FIG. 6 (or FIG. 7), the voltage of the first word line is discharged to the first voltage in the first stage.

Operation 1040: applying a pre pulse voltage to the first word line in a second phase of performing the second read operation, in which the second phase is after the first phase and the pre pulse voltage is greater than the second voltage.

For example, in the case where the read instruction is received after the first instruction is received, please refer to the voltage variation of the first word line indicated by the light-colored line in FIG. 6 (or FIG. 7), the voltage of the first word line is pulled up to the pre pulse voltage from the second voltage in the second phase of performing the second read operation. In the case where the first instruction is not received and the read instruction is received, please refer to the voltage variation of the first word line indicated by the dark-colored line in FIG. 6 (or FIG. 7), the voltage of the first word line is pulled up to the pre pulse voltage from the first voltage in the second stage.

According to the technical solution provided by the example of the present disclosure, the way in which the memory performs the read instruction is changed through the first instruction, so that the memory supports the use of two different ways to apply word line voltages in the read operation, thereby considering different read scenarios.

In some examples, the time taken to pull up the voltage of the first word line to the pre pulse voltage from the second voltage is less than the time taken to pull up the voltage of the first word line to the pre pulse voltage from the first voltage.

For example, please refer to FIG. 6, in this example, the boosting rate of pulling up the voltage of the first word line to the pre pulse voltage from the second voltage is similar to the boosting rate of pulling up the voltage of the first word line to the pre pulse voltage from the first voltage, however, since the second voltage is larger, the time taken to pull up the voltage of the first word line to the pre pulse voltage from the second voltage is less than the time taken to pull up the voltage of the first word line to the pre pulse voltage from the first voltage. It can be learned that, by using the foregoing method, the voltage of the first word line is pulled up to the pre pulse voltage from the second voltage, and since the time taken to pull up the voltage to the pre pulse voltage is shorter, the read time can be shortened, thereby improving the bandwidth for data read. The method is suitable for some small-capacity memory systems.

In some examples, the boosting rate of pulling up the voltage of the first word line to the pre pulse voltage from the second voltage is less than the boosting rate of pulling up the voltage of the first word line to the pre pulse voltage from the first voltage.

For example, please refer to FIG. 7, in this example, the time taken to pull up the voltage of the first word line to the pre pulse voltage from the second voltage is equal to the time taken to pull up the voltage of the first word line to the pre pulse voltage from the first voltage. Since the second voltage is greater, the boosting rate of pulling up the voltage of the first word line to the pre pulse voltage from the second voltage is less than the boosting rate of pulling up the voltage of the first word line to the pre pulse voltage from the first voltage. It can be learned that, by using the foregoing method, the voltage of the first word line is pulled up to the pre pulse voltage from the second voltage, and since the boosting rate is slower, the peak current generated during the read operation can be reduced, thereby ensuring power integrity (PI). The method is suitable for some large-capacity memory systems.

In the technical solutions provided in the foregoing examples, control operations for the selected word line (for example, the first word line) are described, and in the following examples, remaining operations involved in the read operation would be described.

In some examples, the foregoing memory cell array includes a first memory string coupled with a first bit line, the first memory string includes a first TSG, a second TSG, a first memory cell, and a second memory cell, with the second memory cell coupled with a second word line.

Since a first read operation and a second read operation in the example of the present disclosure are read operations for the first memory cell, the above described first memory cell may be considered as the selected memory cell, the first memory string may be considered as the selected memory string, and the second word line may be considered as an unselected word line.

In some examples, the above described memory cell array further includes a second memory string, and the second memory string is the unselected memory string when the first read operation and the second read operation are performed. The second memory string includes a second TSG and a second BSG.

The foregoing operation method of the memory further includes at least one of the following operations.

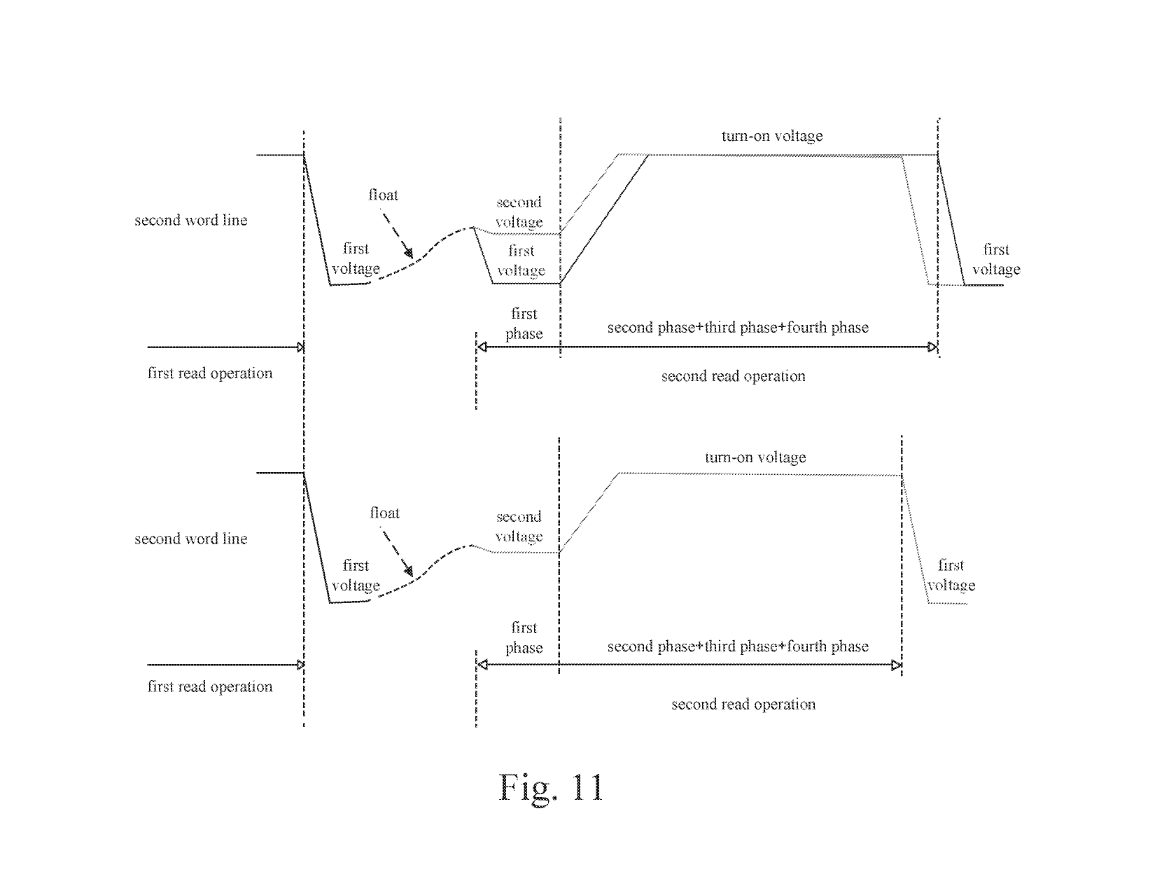

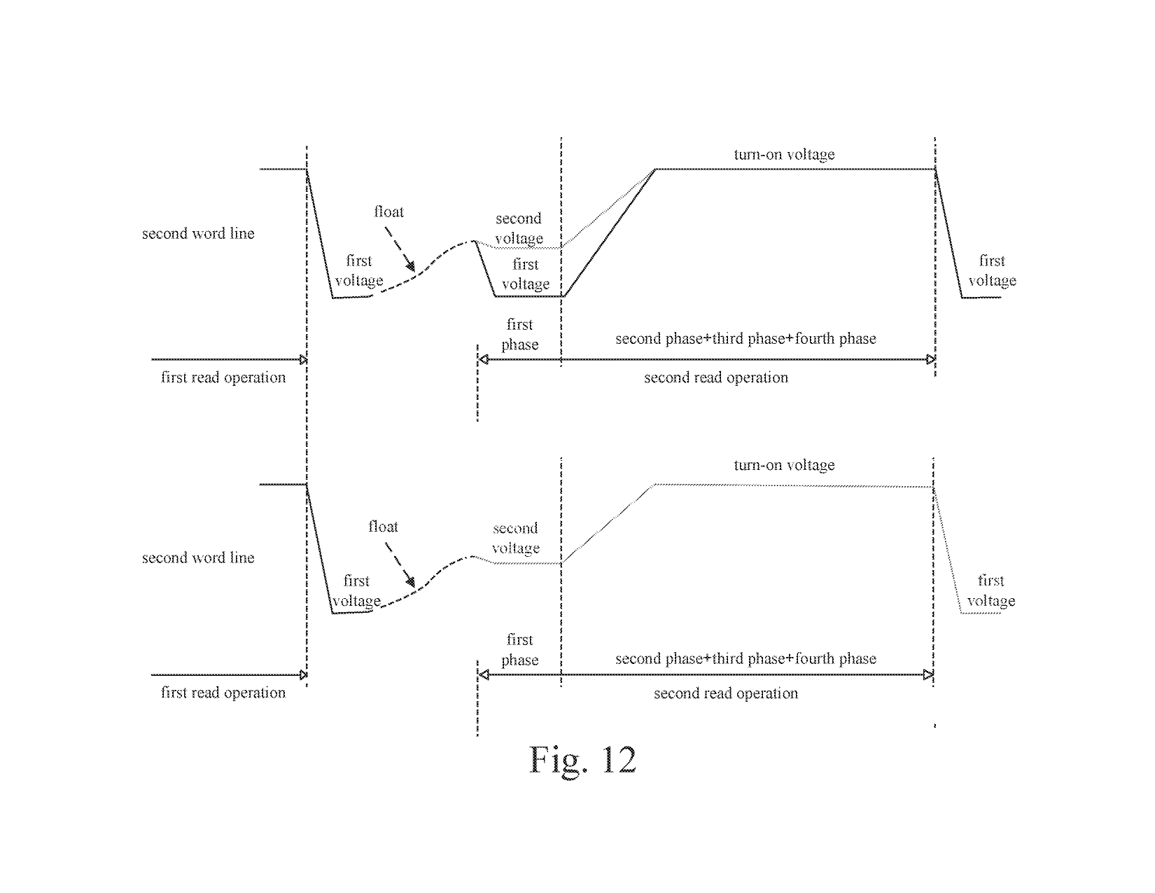

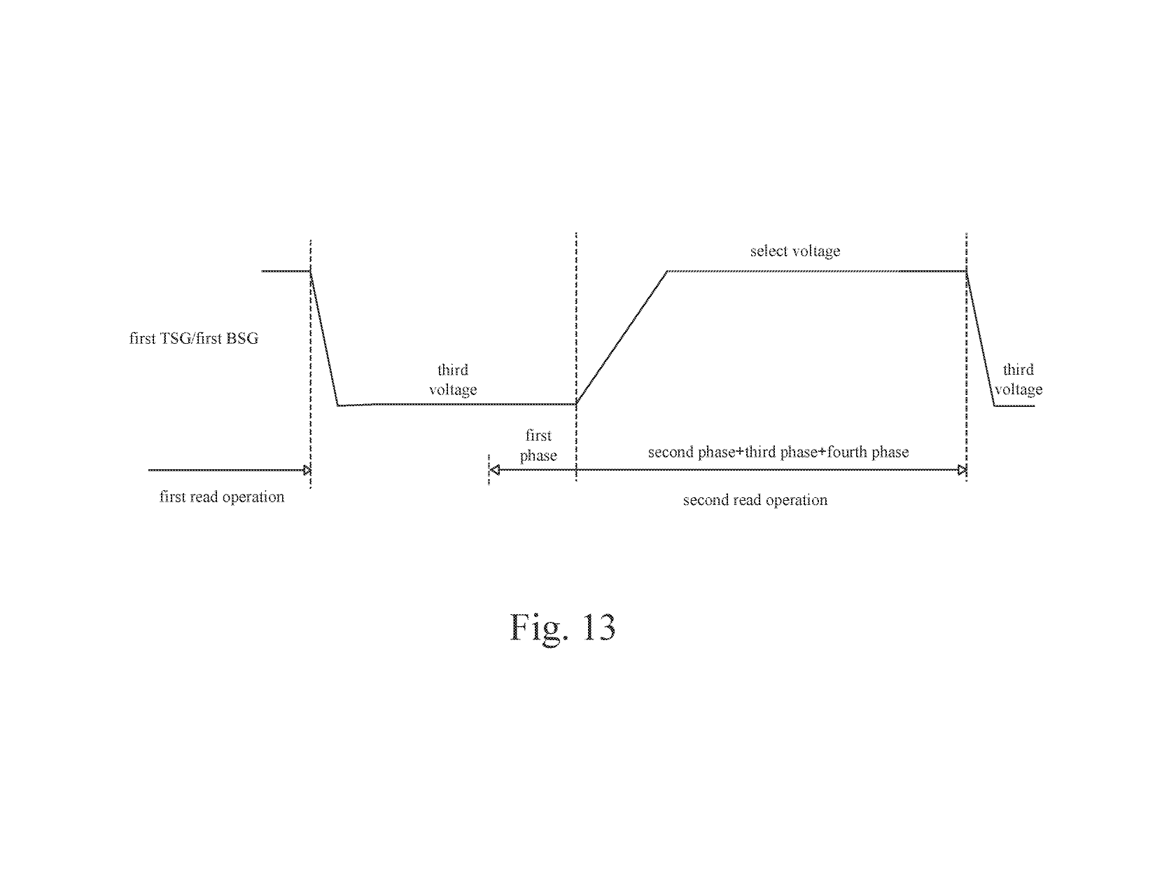

1: After the first read operation is performed, (please refer to FIG. 11 or FIG. 12) a voltage of the second word line is discharged to the first voltage, and (please refer to FIG. 13) a voltage of the first TSG and a voltage of the first BSG are discharged to a third voltage.

In some examples, the third voltage is Vss (the source voltage), and the third voltage is less than the first voltage.

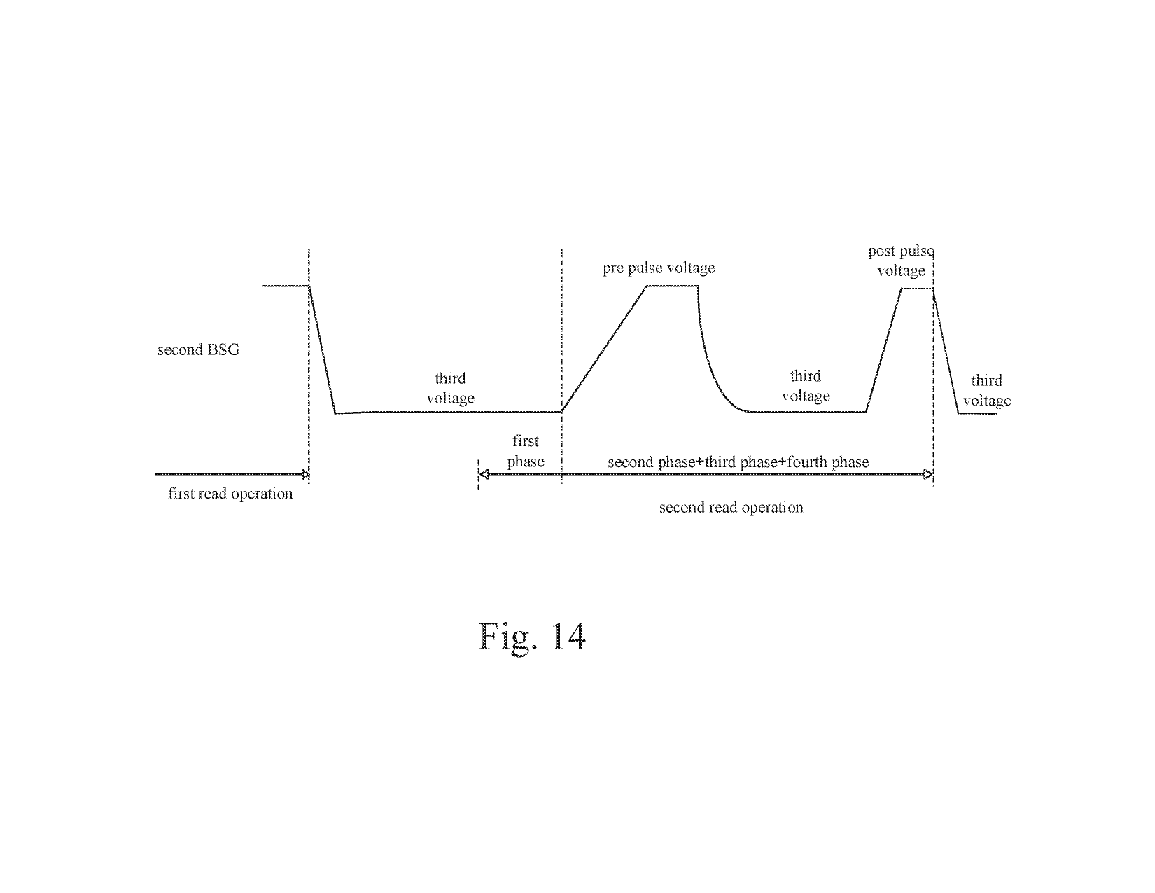

In some examples, after the first read operation is performed, (please refer to FIG. 14) a voltage of the second TSG is discharged to the third voltage.

2: (Please refer to FIG. 11 or FIG. 12) The second word line is floated after the voltage of the second word line is discharged to the first voltage.

As shown in FIG. 11 or FIG. 12, during floating the second word line, the second word line also generates a floating voltage greater than the first voltage.

3: In the first phase, a second voltage is applied to the second word line (please refer to the voltage variation indicated by the light-colored line in FIG. 11 or FIG. 12).

In some examples, in a case where a first-type read instruction is received, the second voltage is applied to the second word line in the first phase. In a case where a second type of read command is received, the voltage of the second word line is discharged to the first voltage in the first phase (please refer to the voltage variation indicated by the dark-colored line in FIG. 11 or FIG. 12).

In some examples, in a case where the read instruction is received after a first instruction is received, the second voltage is applied to the second word line in the first phase. In a case where the first instruction is not received and the read instruction is received, the voltage of the second word line is discharged to the first voltage in the first phase (please refer to the voltage variation indicated by the dark-colored line in FIG. 11 or FIG. 12).

4. In a second phase, a turn-on voltage greater than the second voltage is applied to the second word line, and a select voltage greater than the third voltage is applied to the first TSG and the first BSG.

In some examples, please refer to FIG. 11 or FIG. 12, in the second phase, a third phase, and a fourth phase, the turn-on voltage is applied to the second word line. After the second read operation is performed, the voltage of the second word line is discharged to the first voltage.

In some examples, please refer to FIG. 13, in the second phase, the third phase, and the fourth phase, the select voltage greater than the third voltage is applied to the first TSG and the first BSG respectively. After the second read operation is performed, the voltage of the first TSG and the voltage of the first BSG are respectively discharged to the third voltage.

In some examples, please refer to FIG. 14, after the end of the first phase (e. g., during a first period of the second phase), a pre pulse voltage is applied to the second TSG. After the pre pulse voltage is applied to the second TSG, the voltage of the second TSG is discharged to the third voltage (for example, in a second period of the second phase (the second period is after the first period) and in the third phase, the voltage of the second TSG is discharged to the third voltage, so that the second memory string is deactivated in advance before the read voltage is applied to the first word line). After the voltage of the second TSG is discharged to the third voltage, a post pulse voltage is applied to the second TSG (for example, in the fourth phase, the post pulse voltage is applied to the second TSG). After the second read operation is performed (after the post pulse voltage is applied to the second TSG), the voltage of the second TSG is discharged to the third voltage.

It should be noted that, in the foregoing example, discharging the voltage of the second TSG to the third voltage in the process of the second read operation already functions to deactivate the second memory string, and therefore, in the process of the second read operation, the way to control the voltage of the second BSG may be the same as the first BSG or the same as the second TSG, which is not limited in the present disclosure.

In some examples, please refer to FIG. 11, the time taken to pull up the voltage of the second word line to the turn-on voltage from the second voltage is less than the time taken to pull up the voltage of the second word line to the turn-on voltage from the first voltage.

In some examples, please refer to FIG. 12, the boosting rate of pulling up the voltage of the second word line to the turn-on voltage from the second voltage is less than the boosting rate of pulling up the voltage of the second word line to the turn-on voltage from the first voltage.

According to the technical solution provided by the example of the present disclosure, in the process of the second read operation, with respect to the unselected word line (the second word line), boosting by using the voltage generated by the floating operation is also achieved, so that the boosting process is reasonably controlled.

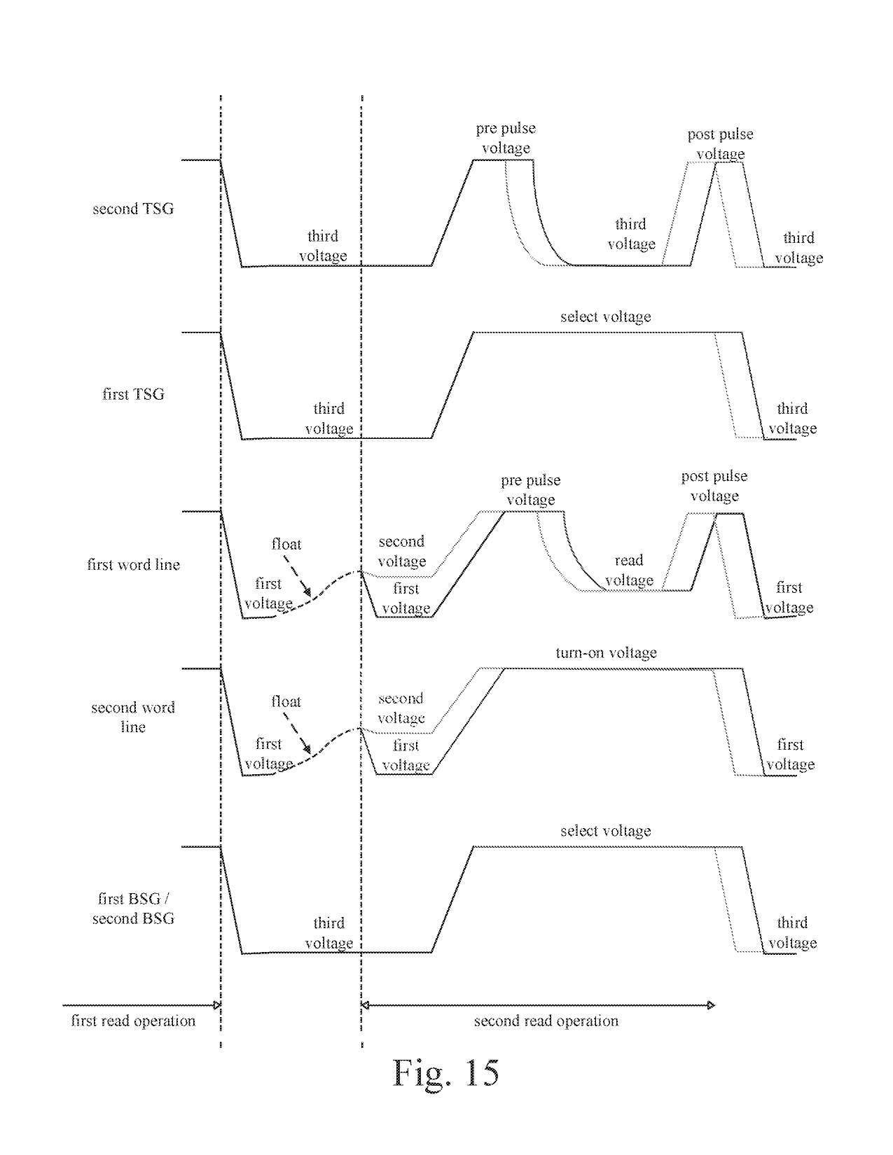

For example, please refer to FIG. 15, the light-colored lines in FIG. 15 indicate the voltage variation of the devices (the first TSG, the second TSG, the first word line, the second word line, the first BSG, and the second BSG) in a case where the floating voltage is used (in a case where a first-type read instruction is received or in a case where a read instruction is received after a first instruction is received), and the dark-colored lines indicate the voltage variation of the devices in a case where the floating voltage is not used (in a case where a second-type read instruction is received, or in a case where a first instruction is not received and a read instruction is received). It can be seen that, in this example, the time taken to pull up the voltage of the first word line to the pre pulse voltage from the second voltage is less than the time taken to pull up the voltage of the first word line to the pre pulse voltage from the second voltage, and the time taken to pull up the voltage of the second word line to the turn-on voltage from the second voltage is less than the time taken to pull up the voltage of the second word line to the turn-on voltage from the first voltage. Therefore, the overall time of the read operation is shortened.

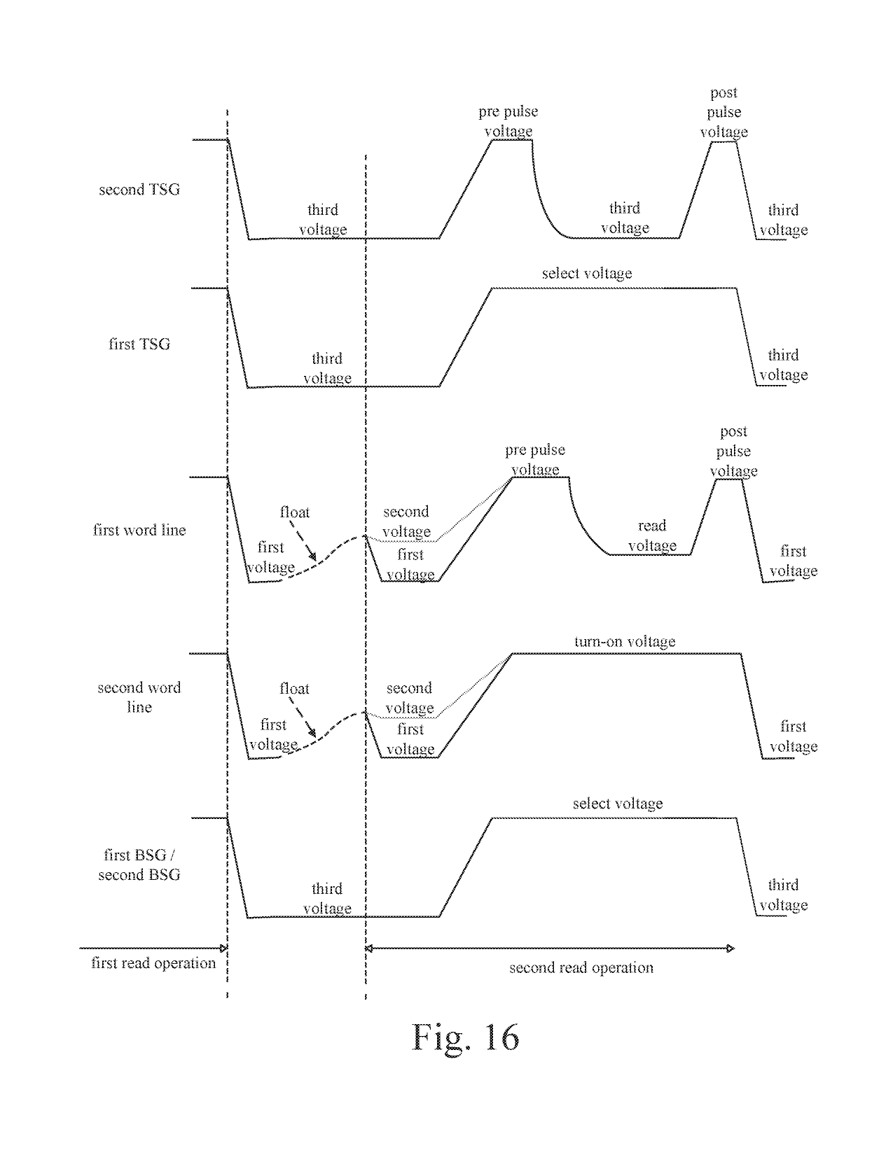

For example, please refer to FIG. 16, the light-colored lines in FIG. 16 indicate the voltage variation of the devices in a case where the floating voltage is used (in a case where the first-type read instruction is received or in a case where the read instruction is received after the first instruction is received), and the dark-colored lines indicate the voltage variation of the devices in a case where the floating voltage is not used (in a case where the second-type read instruction is received, or in a case where the first instruction is not received and the read instruction is received). It can be seen that, in this example, the boosting rate of pulling up the voltage of the first word line to the pre pulse voltage from the second voltage is less than the boosting rate of pulling up the voltage of the first word line to the pre pulse voltage from the first voltage, and the boosting rate of pulling up the voltage of the second word line to the turn-on voltage from the second voltage is less than the boosting rate of pulling up the voltage of the second word line to the turn-on voltage from the first voltage. Therefore, the peak current of the read operation is reduced.

In addition, it can be learned from the foregoing examples that, in the present disclosure, by designing an initial voltage of a boosting process of a word line in a read operation to achieve various beneficial effects described above without interfering with a flow process and a time sequence after the boosting process (for example, the flow process and time sequence after the voltage of the first word line reaches the pre pulse voltage), the various beneficial effects described above can be achieved under the premise that the accuracy of the data read out by the read operation is not affected.

The following is a memory example of the present disclosure, and for details not disclosed in the memory example of the present disclosure, please refer to the examples of the operation method of the memory of the present disclosure.

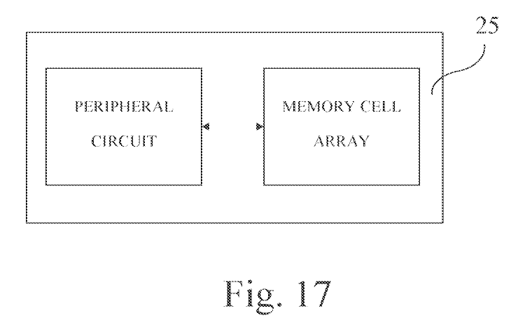

Please refer to FIG. 17, which illustrates a schematic diagram of a memory provided by an example of the present disclosure. The memory 25 includes a peripheral circuit and a memory cell array including a first memory cell coupled with a first word line.

The foregoing peripheral circuit is configured to: discharge a voltage of the first word line to a first voltage after performing a first read operation on the first memory cell; float the first word line after discharging the voltage of the first word line to the first voltage; apply a second voltage to the first word line in a first phase of performing a second read operation, in which the second read operation is after floating the first word line and the second voltage is greater than the first voltage; and apply a pre pulse voltage to the first word line in a second phase of performing the second read operation, in which the second phase is after the first phase and the pre pulse voltage is greater than the second voltage.

In some examples, during floating the first word line, the first word line generates a floating voltage that is greater than the first voltage.

In some examples, the data read from the first memory cell by the first read operation and the data read from the first memory cell by the second read operation belong to different pages.

In some examples, the peripheral circuit is further configured to: apply a read voltage to the first word line in a third phase of performing the second read operation, in which the third phase is after the second phase and the read voltage is less than the pre pulse voltage; apply a post pulse voltage to the first word line in a fourth phase of performing the second read operation, in which the post pulse voltage is greater than the read voltage and the fourth phase is after the third phase; and discharge the voltage of the first word line to the first voltage after performing the second read operation.

In some examples, the peripheral circuit is further configured to: in a case where a first-type read instruction is received, perform the applying the second voltage to the first word line in the first phase of performing the second read operation on the first memory cell; in a case where a second-type read instruction is received, discharge the voltage of the first word line to the first voltage in the first phase; wherein the first-type read instruction and the second-type read instruction are read instructions of two different types.

In some examples, the peripheral circuit is further configured to: in a case where a read instruction is received after a first instruction is received, perform the applying the second voltage to the first word line in the first phase of performing the second read operation on the first memory cell; and in a case where the first instruction is not received and the read instruction is received, discharge the voltage of the first word line to the first voltage in the first phase.

In some examples, the time taken to pull up the voltage of the first word line to the pre pulse voltage from the second voltage is less than the time taken to pull up the voltage of the first word line to the pre pulse voltage from the first voltage.

In some examples, the boosting rate of pulling up the voltage of the first word line to the pre pulse voltage from the second voltage is less than the boosting rate of pulling up the voltage of the first word line to the pre pulse voltage from the first voltage.

In some examples, the memory cell array includes a first memory string coupled with a first bit line, the first memory string including a first TSG, a first BSG, the first memory cell, and a second memory cell, with the second memory cell coupled with a second word line.

The peripheral circuit is further configured to: discharge a voltage of the second word line to the first voltage, and discharge a voltage of the first TSG and a voltage of the first BSG to a third voltage after the first read operation is performed; float the second word line after discharging the voltage of the second word line to the first voltage; apply the second voltage to the second word line in the first phase; apply a turn-on voltage greater than the second voltage to the second word line, and apply a select voltage greater than the third voltage to the first TSG and the first BSG in the second phase.

In some examples, a memory system is further provided, the memory system includes: at least one memory, the memory including a peripheral circuit and a memory cell array, the memory cell array including a first memory cell coupled with a first word line, the peripheral circuit configured to implement an operation method of the memory; and a controller coupled to the at least one memory to control the at least one memory to store data.

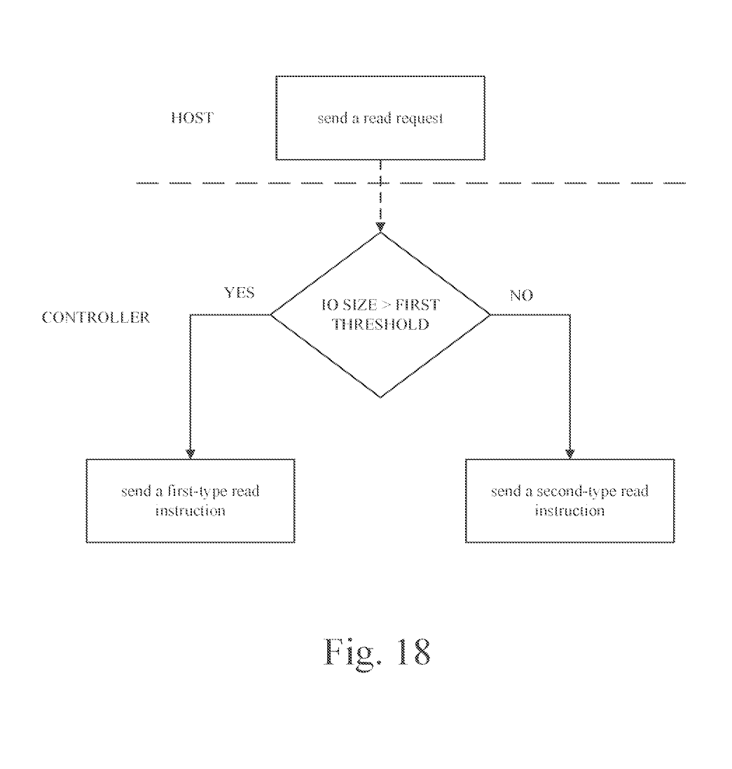

In some examples, as shown in FIG. 18, the controller is configured to: receive a read request (sent by the host); in a case where the input output size (IO size) corresponding to the read request is greater than a first threshold, send a first-type read instruction; and in a case where the IO size corresponding to the read request is not greater than the first threshold, send a second-type read instruction.

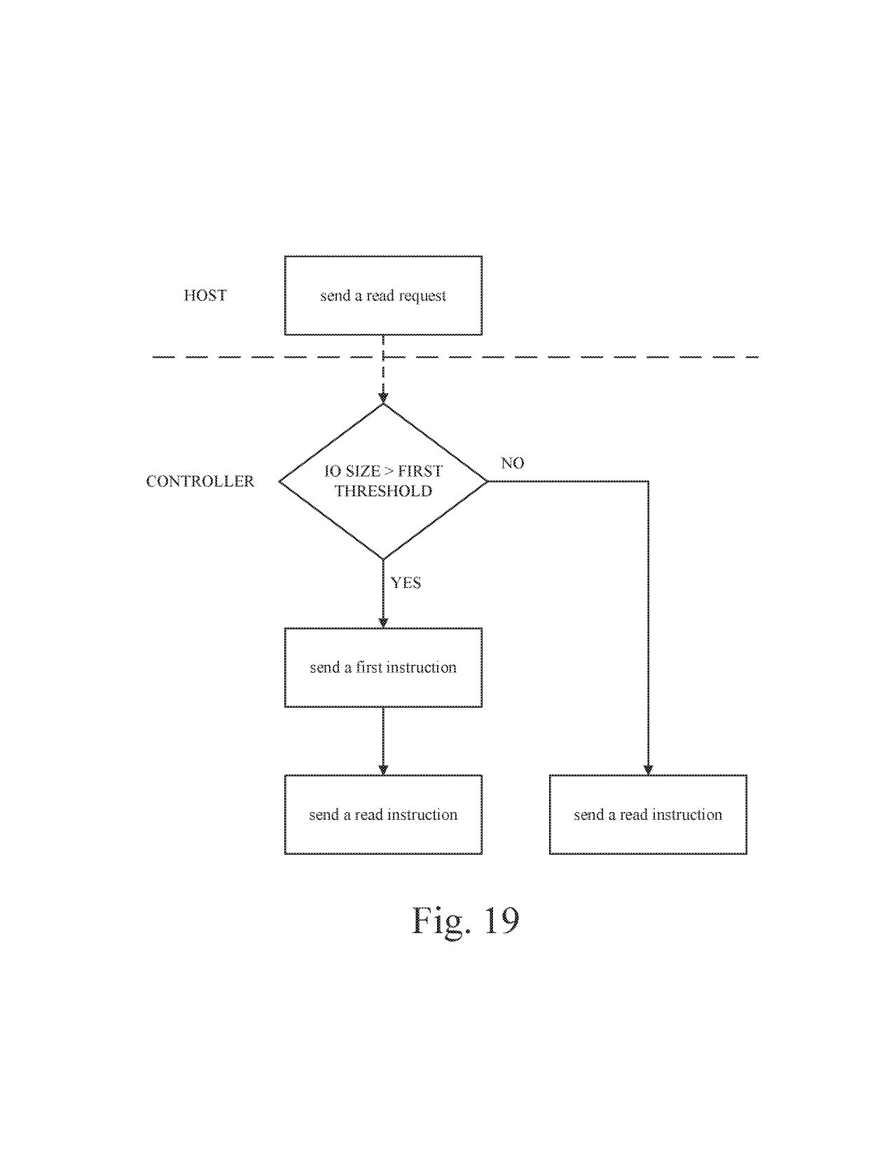

In some examples, as shown in FIG. 19, the controller is configured to: receive a read request (sent by the host); in a case where the IO size corresponding to the read request is greater than the first threshold, send a first instruction and then send a read instruction; and in a case where the IO size corresponding to the read request is not greater than the first threshold, send the read instruction.

In some examples, the IO size corresponding to the read request being greater than the first threshold reflects that the read request is configured to request a sequential reading, and the IO size corresponding to the read request being not greater than the first threshold reflects that the read request is configured to request a random reading. The first threshold is configured by the technician as required, which is not limited in the present disclosure.

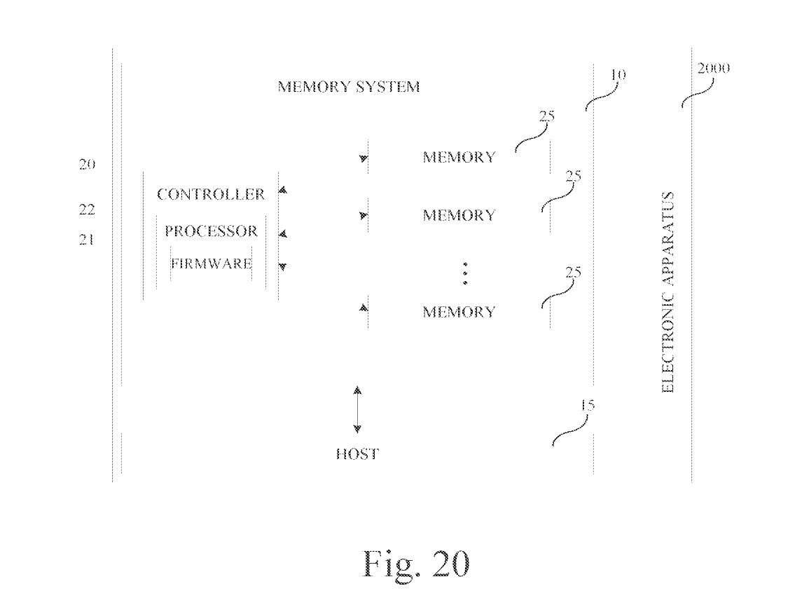

Please refer to FIG. 20, which illustrates a structural block diagram of an electronic apparatus provided by an example of the present disclosure.

The electronic apparatus 2000 includes a memory system 10 and a host 15.

The memory system 10 may include a controller 20 and one or more memories 25. The memory system 10 is coupled to the host 15. The memory 25 includes a peripheral circuit and a memory cell array, the memory cell array including a first memory cell coupled with a first word line, and the peripheral circuit configured to implement the foregoing operation method of the memory. The controller 20 is coupled to the at least one memory 25 to control the at least one memory 25 to store data. The controller 20 may run a firmware 21, which may be executed by one or more processors 22 of the controller 20 to enable the control of the memory.

For specific descriptions of the memory system 10 and the host 15, please refer to the foregoing examples, and details are not described herein again.

Reference herein to “a plurality of” means two or more. “and/or” describes an association relationship of associated objects, and indicates that there may be three kind of relationships, for example, A and/or B may indicate three cases: A alone, A and B together, and B alone. The character “/” generally indicates that the previous and next associated objects are in an “or” relationship.

The foregoing descriptions are merely optional examples of the present disclosure, and are not intended to limit the present disclosure, and any modification, equivalent replacement, improvement, and the like made within the spirit and principle of the present disclosure shall be included in the protection scope of the present disclosure.

What is claimed is:

1. An operation method of a memory comprising a memory cell array that comprises a first memory cell coupled with a first word line, the operation method comprising:
discharging a voltage of the first word line to a first voltage after performing a first read operation on the first memory cell;
floating the first word line after discharging the voltage of the first word line to the first voltage;
applying a second voltage to the first word line in a first phase of performing a second read operation on the first memory cell, wherein the second read operation is after floating the first word line and the second voltage is greater than the first voltage; and
applying a pre pulse voltage to the first word line in a second phase of performing the second read operation, wherein the second phase is after the first phase and the pre pulse voltage is greater than the second voltage.

2. The operation method of claim 1, wherein the first word line generates a floating voltage that is greater than the first voltage during floating the first word line.

3. The operation method of claim 1, wherein data read from the first memory cell by the first read operation and data read from the first memory cell by the second read operation belong to different pages.

4. The operation method of claim 1, further comprising:
applying a read voltage to the first word line in a third phase of performing the second read operation, wherein the third phase is after the second phase and the read voltage is less than the pre pulse voltage;
applying a post pulse voltage to the first word line in a fourth phase of performing the second read operation, wherein the post pulse voltage is greater than the read voltage and the fourth phase is after the third phase; and
discharging the voltage of the first word line to the first voltage after performing the second read operation.

5. The operation method of claim 1, further comprising:
responsive to receiving a first-type read instruction, performing the applying the second voltage to the first word line in the first phase of performing the second read operation on the first memory cell; and
responsive to receiving a second-type read instruction, discharging the voltage of the first word line to the first voltage in the first phase,
wherein the first-type read instruction and the second-type read instruction are read instructions of two different types.

6. The operation method of claim 1, further comprising:
responsive to receiving a read instruction after a first instruction is received, performing the applying the second voltage to the first word line in the first phase of performing the second read operation on the first memory cell; and
responsive to not receiving the first instruction and receiving the read instruction, discharging the voltage of the first word line to the first voltage in the first phase.

7. The operation method of claim 5, wherein a time taken to pull up the voltage of the first word line to the pre pulse voltage from the second voltage is less than a time taken to pull up the voltage of the first word line to the pre pulse voltage from the first voltage.

8. The operation method of claim 5, wherein a boosting rate of pulling up the voltage of the first word line to the pre pulse voltage from the second voltage is less than a boosting rate of pulling up the voltage of the first word line to the pre pulse voltage from the first voltage.

9. The operation method of claim 1, wherein the memory cell array comprises a first memory string coupled with a first bit line, the first memory string comprising a first top select gate (TSG), a first bottom select gate (BSG), the first memory cell, and a second memory cell, with the second memory cell coupled with a second word line, and
the method further comprises:
discharging a voltage of the second word line to the first voltage, and discharging a voltage of the first TSG and a voltage of the first BSG to a third voltage after performing the first read operation;
floating the second word line after discharging the voltage of the second word line to the first voltage;
applying the second voltage to the second word line in the first phase; and
applying a turn-on voltage greater than the second voltage to the second word line, and applying a select voltage greater than the third voltage to the first TSG and the first BSG in the second phase.

10. A memory comprising a peripheral circuit and a memory cell array, wherein the memory cell array comprises a first memory cell coupled with a first word line, and wherein the peripheral circuit is configured to:
discharge a voltage of the first word line to a first voltage after performing a first read operation on the first memory cell;
float the first word line after discharging the voltage of the first word line to the first voltage;
apply a second voltage to the first word line in a first phase of performing a second read operation on the first memory cell, wherein the second read operation is after floating the first word line and the second voltage is greater than the first voltage; and
apply a pre pulse voltage to the first word line in a second phase of performing the second read operation, wherein the second phase is after the first phase and the pre pulse voltage is greater than the second voltage.

11. The memory of claim 10, wherein the first word line generates a floating voltage that is greater than the first voltage during floating the first word line.

12. The memory of claim 10, wherein data read from the first memory cell by the first read operation and data read from the first memory cell by the second read operation belong to different pages.

13. The memory of claim 10, wherein the peripheral circuit is further configured to:
apply a read voltage to the first word line in a third phase of performing the second read operation, wherein the third phase is after the second phase and the read voltage is less than the pre pulse voltage;
apply a post pulse voltage to the first word line in a fourth phase of performing the second read operation, wherein the post pulse voltage is greater than the read voltage and the fourth phase is after the third phase; and
discharge the voltage of the first word line to the first voltage after performing the second read operation.

14. The memory of claim 10, wherein the peripheral circuit is further configured to:
responsive to receiving a first-type read instruction, perform the applying the second voltage to the first word line in the first phase of performing the second read operation on the first memory cell; and
responsive to receiving a second-type read instruction, discharge the voltage of the first word line to the first voltage in the first phase,
wherein the first-type read instruction and the second-type read instruction are read instructions of two different types.

15. The memory of claim 10, wherein the peripheral circuit is further configured to:
responsive to receiving a read instruction after a first instruction is received, perform the applying the second voltage to the first word line in the first phase of performing the second read operation on the first memory cell; and
responsive to not receiving the first instruction and receiving the read instruction, discharging the voltage of the first word line to the first voltage in the first phase.

16. The memory of claim 14, wherein a time taken to pull up the voltage of the first word line to the pre pulse voltage from the second voltage is less than a time taken to pull up the voltage of the first word line to the pre pulse voltage from the first voltage.

17. The memory of claim 14, wherein a boosting rate of pulling up the voltage of the first word line to the pre pulse voltage from the second voltage is less than a boosting rate of pulling up the voltage of the first word line to the pre pulse voltage from the first voltage.

18. The memory of claim 10, wherein the memory cell array comprises a first memory string coupled with a first bit line, the first memory string comprising a first top select gate (TSG), a first bottom select gate (BSG), the first memory cell, and a second memory cell, with the second memory cell coupled with a second word line, and
the peripheral circuit is further configured to:
discharge a voltage of the second word line to the first voltage, and discharge a voltage of the first TSG and a voltage of the first BSG to a third voltage after performing the first read operation;
float the second word line after discharging the voltage of the second word line to the first voltage;
apply the second voltage to the second word line in the first phase; and
apply a turn-on voltage greater than the second voltage to the second word line, and apply a select voltage greater than the third voltage to the first TSG and the first BSG in the second phase.

19. A memory system, comprising:
at least one memory comprising a peripheral circuit and a memory cell array, wherein the memory cell array comprising a first memory cell coupled with a first word line, and wherein the peripheral circuit is configured to:
discharge a voltage of the first word line to a first voltage after performing a first read operation on the first memory cell;
float the first word line after discharging the voltage of the first word line to the first voltage;
apply a second voltage to the first word line in a first phase of performing a second read operation on the first memory cell, wherein the second read operation is after floating the first word line and the second voltage is greater than the first voltage; and
apply a pre pulse voltage to the first word line in a second phase of performing the second read operation, wherein the second phase is after the first phase and the pre pulse voltage is greater than the second voltage, and
a controller coupled to the at least one memory to control the at least one memory to store data.

20. The memory system of claim 19, further comprising:
a host coupled to the controller.
